(19) United States
(12) Patent Application Publication
(10) Pub. No.: US 2024/0080631 A1
(43) Pub. Date: Mar. 7, 2024

(54) SEALED ACOUSTIC COUPLER FOR MICRO-ELECTROMECHANICAL SYSTEMS MICROPHONES

(71) Applicant: GM Cruise Holdings LLC, San Francisco, CA (US)

(72) Inventors: Anurup Guha, Sunnyvale, CA (US); Amanda Lind, Brooklyn, NY (US); Sally Abolitz, Pacifica, CA (US)

(21) Appl. No.: 17/939,700

(22) Filed: Sep. 7, 2022

(51) Int. Cl. H04R 19/04; B81B 7/00; H04R 1/04; H04R 1/08; H04R 1/40

(52) U.S. Cl. CPC H04R 19/04; B81B 7/0058; H04R 1/04; H04R 1/086; H04R 1/406; B60W 60/00; B81B 2201/0257; H04R 2201/003; H04R 2499/13

(57) ABSTRACT

Aspects of the present disclosure relate to sealing and protecting micro-electromechanical systems (MEMS) microphones. In some cases, a MEMS microphone protection apparatus may include a housing, at least one acoustic port extending through the housing providing an aperture; and at least one membrane positioned within the at least one acoustic port. In some examples, the membrane can seal the at least one acoustic port.

### TECHNICAL FIELD

The present disclosure generally relates to micro-electromechanical systems (MEMS) microphones. For example, aspects of the present disclosure relate to techniques and systems for protecting MEMS microphones.

### BACKGROUND

An autonomous vehicle is a motorized vehicle that can navigate without a human driver. An exemplary autonomous vehicle can include various sensors, such as a camera sensor, a light detection and ranging (LIDAR) sensor, and a radio detection and ranging (RADAR) sensor, among others. The sensors collect data and measurements that the autonomous vehicle can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system. In some cases, the autonomous vehicle may include acoustic sensors such as micro-electromechanical systems (MEMS) microphones that are highly sensitive and susceptible to damage.

### BRIEF DESCRIPTION OF THE DRAWINGS

The various advantages and features of the present technology will become apparent by reference to specific implementations illustrated in the appended drawings. A person of ordinary skill in the art will understand that these drawings only show some examples of the present technology and would not limit the scope of the present technology to these examples. Furthermore, the skilled artisan will appreciate the principles of the present technology as described and explained with additional specificity and detail through the use of the accompanying drawings in which:

FIG. 1A is a diagram illustrating a perspective view of a MEMS microphone array protective apparatus, in accordance with some examples of the present disclosure;

FIG. 1B is a diagram illustrating a partial cross-sectional view of a MEMS microphone array protective apparatus, in accordance with some examples of the present disclosure;

FIG. 2A is a diagram illustrating a perspective view of a sealed MEMS microphone array protection apparatus, in accordance with some examples of the present disclosure;

FIG. 2B is a diagram illustrating a rear view of a sealed MEMS microphone array protection apparatus, in accordance with some examples of the present disclosure;

FIG. 2C is a diagram illustrating a partial cross-sectional view of the front of a sealed MEMS microphone array protection apparatus, in accordance with some examples of the present disclosure;

FIG. 3 is a diagram illustrating a vehicle having a sealed MEMS microphone array protection apparatus, in accordance with some examples of the present disclosure; and

FIG. 4 is a diagram illustrating an example system environment that can be used to facilitate autonomous vehicle (AV) navigation and routing operations, in accordance with some examples of the present disclosure.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

One aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

The term “coupled” is defined as connected, whether directly or indirectly through intervening components, and is not necessarily limited to physical connections. The connection can be such that the objects are permanently connected or releasably connected.

As previously explained, autonomous vehicles (AVs) can include various sensors, such as a camera sensor, a light detection and ranging (LIDAR) sensor, a radio detection and ranging (RADAR) sensor, an acoustic sensor, amongst others, which the AVs can use to collect data and measurements that the AVs can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system.

In some aspects, AV sensors may be mounted or positioned on the exterior of the AV at locations where they are exposed to the environment and more susceptible to damage or interference. For example, an AV may have one or more microelectromechanical systems (MEMS) microphones that are positioned on the exterior of the AV. In some cases, the MEMS microphones located on the exterior of the AV can suffer degraded performance and/or failure due to water intrusion, dirt, dust, debris, etc.

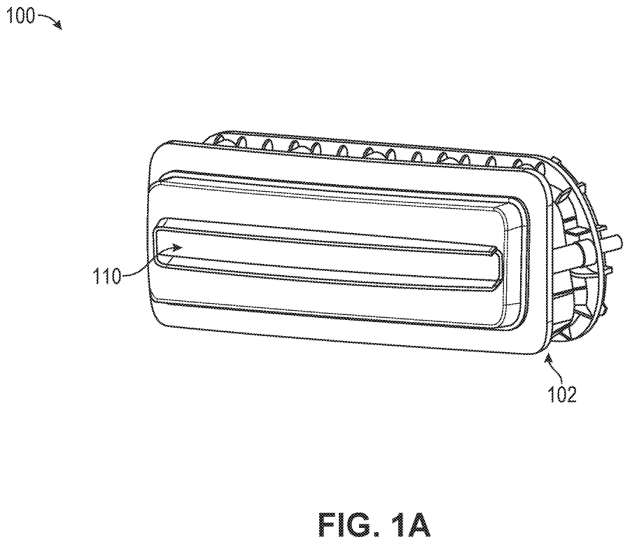

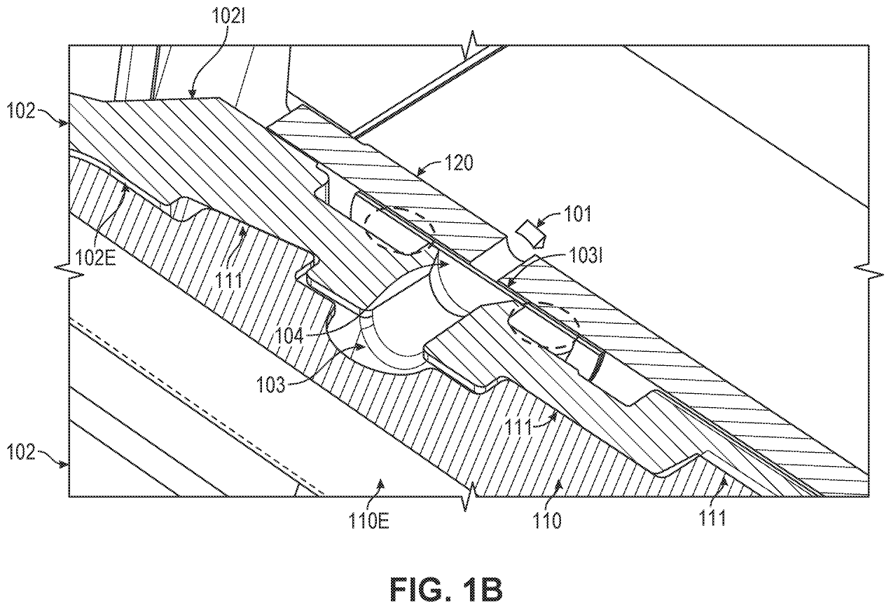

FIG. 1A is a diagram illustrating an example micro-electromechanical systems (MEMS) microphone array protective apparatus 100. In some aspects, MEMS microphone protective apparatus 100 can include a housing 102 and a protective member such as protector 110. In some cases, protector 110 can be a removable component of housing 102. In some instances, protector 110 can be formed together with housing 102.

FIG. 1B is a diagram illustrating a cross-sectional view of MEMS microphone array protective apparatus 100. As noted with respect to FIG. 1A, MEMS microphone array protective apparatus 100 can include a housing 102 and a protector 110. In some examples, MEMS microphone protective apparatus 100 may include one or more MEMS such as MEMS microphone 101.

In some instances, the housing 102 can include one or more openings such as aperture 103. In some cases, aperture 103 can be a complete aperture that extends through the housing 102. In some examples, aperture 103 may be a partial aperture that extends through a portion of housing 102. In some aspects, the interior 1021 of housing 102 can include an intermediate barrier 104 that may be positioned against the interior edge 1031 of aperture 103. In some instances, intermediate barrier 104 can be configured to create a seal that can be used to protect MEMS microphone 101 (e.g., prevent ingest of water, dust, debris, etc. from contacting MEMS microphone 101). In some cases, aperture 103 can be aligned with MEMS microphone 101 that is mounted or affixed to a printed circuit board (“PCB”) 120 (e.g., MEMS microphone 101 can be positioned at the aperture 103).

In some aspects, the exterior 102E of the housing 102 can be configured to connect with protector 110. In some cases, protector 110 can be dimensioned to have grooves 111 that are adapted to tangentially fit with the exterior 102E of the housing 102 (e.g., protector 110 can cover aperture 103). In some cases, protector 110 can provide protection while permitting acoustic and/or ultrasonic communication (e.g., protector 110 can be acoustically permeable). In some instances, exterior 110E of the protector 110 can have a planar or substantially planar shape. In some examples, protector 110 may shield MEMS microphone 101 from dirt, water, debris, etc. While FIG. 1B is illustrated with a single MEMS component (e.g., MEMS microphone 101), one of ordinary skill in the art will understand that additional or fewer components in similar or alternative configurations are contemplated herein. The illustrations and examples provided in the present disclosure are for conciseness and clarity. Other examples may include different numbers and/or types of elements, but one of ordinary skill the art will appreciate that such variations do not depart from the scope of the present disclosure.

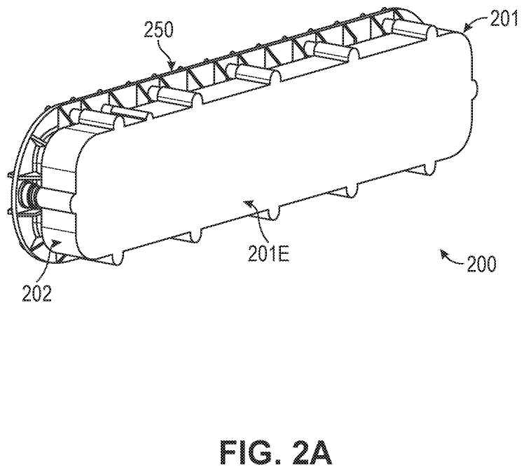

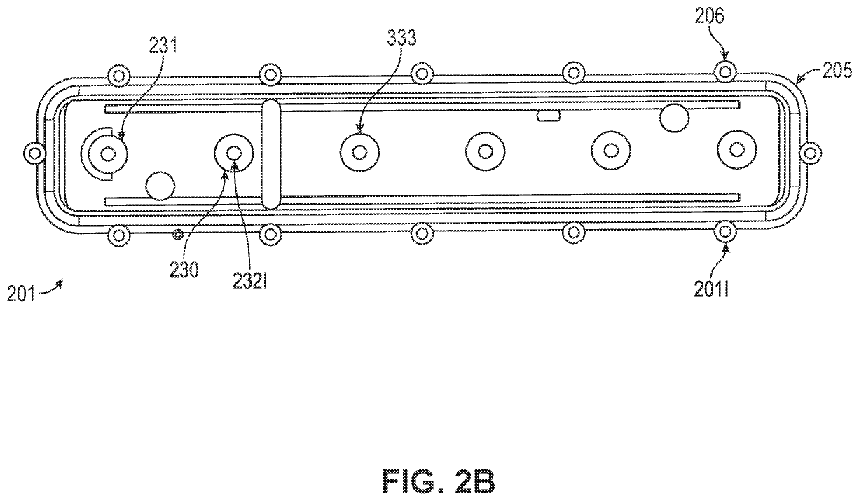

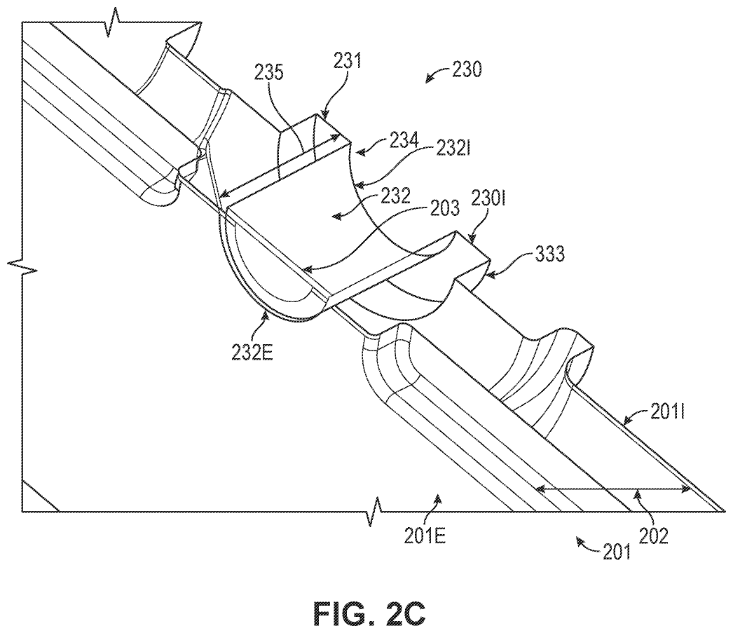

FIG. 2A illustrates an example of a sealed micro-electromechanical system (MEMS) microphone protective apparatus 200. In some aspects, MEMS microphone protective apparatus 200 can include a sealed housing 201. In some examples, the exterior surface 201E of the sealed housing 201 can be flush or flat. In some cases, the sealed housing 201 can be monolithic. In some examples, the sealed housing 201 may be constructed from a plastic and/or polyurethane material. In some instances, the sealed housing 201 can be constructed from materials that can withstand high ambient temperatures (e.g., temperatures greater than 100° Fahrenheit). In some cases, sealed housing 201 can be free of apertures or openings (e.g., no openings on the exterior surface 201E or on interior surface 2011 of the sealed housing 201).

In some aspects, sealed housing 201 can provide a watertight exterior surface 201E. In some cases, watertight exterior surface 201E can prevent the permeation of water, dust, debris, etc. into a MEMS device (e.g., MEMS microphone 101 that can be coupled with the MEMS microphone array protective apparatus 200). In some examples, the MEMS microphone array protective apparatus 200 can withstand high water pressure (e.g., greater than 2,500 pounds per square inch (PSI)). In some aspects, sealed housing 201 can result in reduced manufacturing costs and increased production efficiency (e.g., simpler assembly, less parts, etc.).

In some examples, the sealed housing 201 can be coupled to a backplate 250. The backplate 250, in some examples, can house a PCB (e.g., PCB 120) having at least one MEMS device (e.g., MEMS microphone 101). In some cases, the sealed housing 201 can include at least one alignment groove 205 to align the sealed housing 201 to a backplate 250 (see FIG. 1B). In some instances, alignment groove 205 can be used to align a MEMS microphone to an acoustic port 230 of the sealed housing 201. In some examples, backplate 250 can include at least one fastening aperture 206 configured to couple the backplate 250 to a sealed housing 201 (see FIG. 2B). In some aspects, backplate 250 can be coupled to the fastening aperture by screws, bolts, rivets, adhesive anchoring, and/or any other suitable fastening device or mechanism. In some cases, sealed housing 201 and backplate 250 can be coupled in a waterproof manner (e.g., to form a waterproof seal). Non-exhaustive examples of a waterproof manner include, but not limited to, sprayed, injection, lining, coating, rigid, paintable, and/or plaster.

FIG. 2B illustrates a rear view of the sealed housing 201. In some examples, the sealed housing 201 can include at least one acoustic port 230. The acoustic port 230, in some examples, can include an annular formation 231. In some cases, the annular formation 231 can extrude out from the interior surface 2011 of the sealed housing 201. In some examples, the annular formation 231 can have a thinner thickness than a remaining portion of the sealed housing 201.

In some examples, acoustic port 230 can include an annular opening. In at least one example, the annular opening comprises an aperture 234 (e.g., as illustrated in FIG. 2C). The aperture 234, in some examples, can be the same length as the annular formation 231. In some cases, acoustic port 230 can have a depth that is less than or equal to 80 mm. In some instances, acoustic port 230 can couple to a MEMS microphone 101 directly or indirectly. In some cases, the acoustic port 230 can align with a MEMS microphone 101 that is coupled to a PCB 120. In some aspects, the acoustic port can fit directly over a MEMS microphone 101 on a PCB 120. In at least one example, the acoustic port can fit directly over a PCB porthole (not displayed) holding a MEMS microphone 101. In at least one example, the acoustic port can be aligned to coincide with the MEMS microphone 101 placement on a PCB 120. In at least one example, a MEMS microphone 101 can be aligned at the center of the annular formation 231 at the interior edge 2321.

The acoustic port 230, in some examples, can include a MEMS receptor 333 that can be coupled to a MEMS microphone 101. The MEMS receptor 333, in some examples, can be integrated on the interior surface 2301 of the acoustic port 230. In some aspects, the annular formation 231 can be located between the MEMS receptor 333 and a membrane 203 of the sealed housing 201. In some examples, the MEMS receptor 333 can be located within the annular formation 231. In some instances, the MEMS receptor 333 can be directly positioned on the membrane 203. In some cases, the MEMS receptor 333 can be indirectly coupled with a MEMS microphone 101 via a PCB 120 (not displayed). In some aspects, the MEMS receptor 333 can retain MEMS microphone 101 and prevent MEMS microphone 101 from being displaced when the MEMS microphone array protective apparatus 200 is in motion.

FIG. 2C illustrates a partial cross-sectional view of the sealed housing 201. In at least one example, the acoustic port 230 can include a membrane 203. The membrane 203, in some examples, can be a planar surface that is perpendicular and tangential to the circular annular surface 232 of the annular formation 231. In at least one example, the membrane 203 can be located within the annular surface 232. In some examples, the membrane 203 can be positioned at a distance that is between 1 mm to 10 mm inside the annular opening from the exterior edge 232E. The membrane 203, in some examples, can be located at the exterior edge 232E of the annular formation 231. The membrane 203, in some examples, can be positioned concentrically on the exterior edge 232E of the annular formation 231 (e.g., providing a seal). The membrane 203, in some examples, can be located in between the exterior edge 232E and interior edge 2321 of the annular formation 231 while still retaining a watertight seal. In some cases, the membrane 203 can have a thinner width then the width 235 of the annular formation 231. In one illustrative example, the membrane 203 can have a thickness that is less than or equal to 0.15 millimeters (mm). In some examples, the thickness of the membrane 203 can be selected based on the capability of a selected material to withstand varying levels of pressure (e.g., 2000 PSI, 2,500 PSI, 3,000 PSI, etc.)).

In at least one example, sealed housing 201 can have a varying width 202 (e.g., a non-uniform thickness). The sealed housing 201, in some examples, can include at least one membrane 203 having a thinner width or thickness then the remaining housing width 202 of the sealed housing 201. It should be noted the at least one portion having a thinner width then the remaining width 202 of the sealed housing 201 and membrane 203 are used interchangeably in this disclosure. In some examples, the membrane 203 (e.g., portions having a thinner width) can include an aperture 234 from exterior surface 201E through the interior surface 2011 of the sealed housing 201. In some aspects, aperture 234 may not penetrate through the exterior surface 201E. In some examples, a full aperture can penetrate through the exterior surface 201E of the sealed housing 201 (not displayed). In some cases, a membrane 203 can be located the exterior edge 232E of the annular formation 231 such that the membrane 203 is flushed with the exterior surface 201E of the sealed housing 201 and provides a seal. In some examples, sealed housing 201 can be formed without protector 110 or intermediate barrier 104.

In some cases, the aperture 234 can be shaped as an annular formation 231, which can have varying dimensions. In some examples, the annular surface 232 or the annular opening can be dimensioned such that it is shaped to converge in at least a portion of the annular formation 231. In some examples, the annular surface 232 or annular opening can be dimensioned such that it is shaped to diverge in at least a portion of the annular formation 231. The annular surface 232 or annular opening, in some examples, can have a uniform diameter. The annular surface 232 or annular opening, in some examples, can be shaped to include a cone, with the vertex of the cone being positioned either the interior edge 2321 or exterior edge 232E and the base of the cone being positioned at the exterior edge 232E or the interior edge 2321. In some examples, the annular surface 232 or annular opening can include an annular width 235 that can be the same as the width or thickness of the housing width 202. In some examples, the annular surface 232 or annular opening can range from the exterior surface 201E to beyond the interior surface 2011. In some examples, the annular surface 232 or annular opening can have an annular width 235 equal to or less than 80 mm. In some instances, variation of internal annular medium dimension can increase efficiency of the acoustic communications, signal communication, ultrasonic range, and/or functionality of the MEMS microphone.

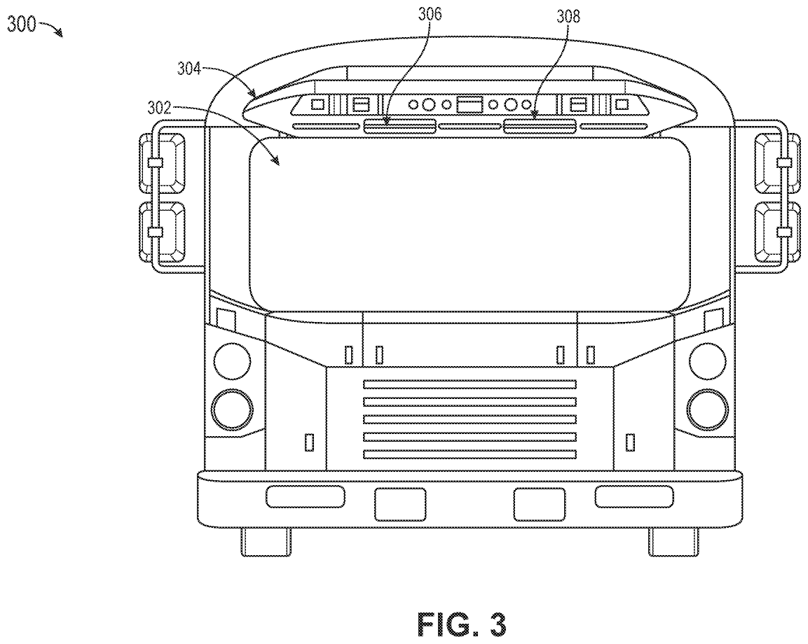

FIG. 3 illustrates an example of a vehicle 300 having one or more MEMS microphone array protection apparatuses. In some examples, vehicle 300 may include structure 304 that can include MEMS microphone array apparatus 306 and/or MEMS microphone array apparatus 308. In some aspects, MEMS microphone array apparatus 306 and/or MEMS microphone array apparatus 308 can correspond to MEMS microphone array protective apparatus 100 and/or to MEMS microphone array protective apparatus 200.

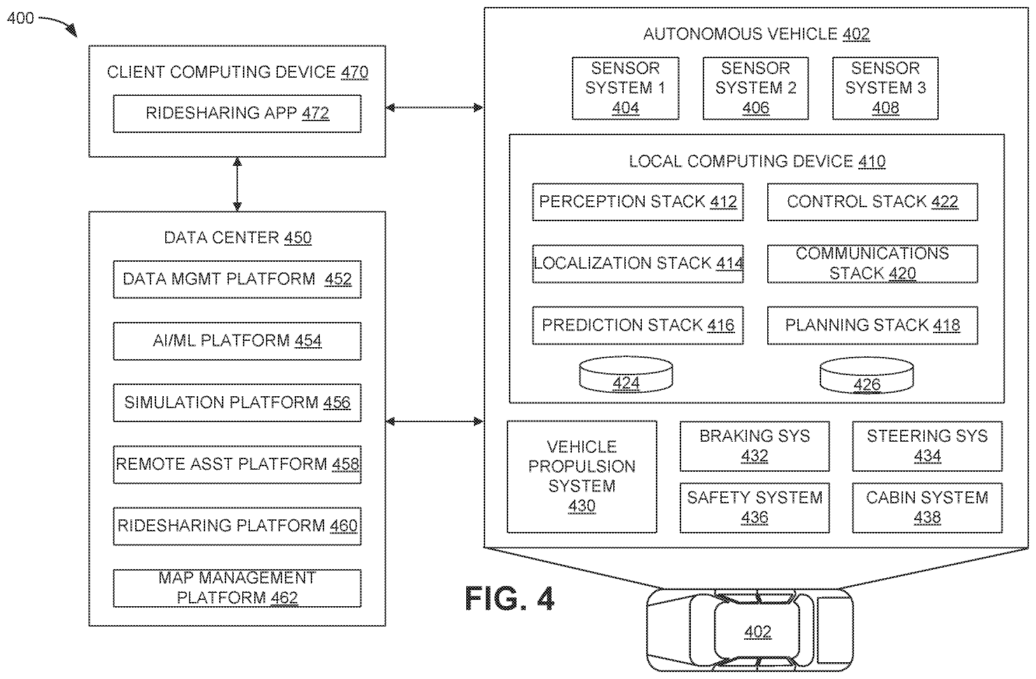

In some cases, structure 304 (e.g., including MEMS microphone array apparatus 306, 308) can be positioned or mounted above windshield 302. In some cases, structure 304 can be positioned or mounted at any other exterior portion of vehicle 300. For example, structure 304 can be positioned at a rear portion of vehicle 300 (not illustrated). In some examples, vehicle 300 can correspond to an autonomous vehicle such as autonomous vehicle 402 described in connection with FIG. 4 herein. In some examples, MEMS microphone array apparatus 306 and/or MEMS microphone array apparatus 308 can include one or more MEMS microphones (e.g., MEMS microphone 101) that correspond to one or more sensor systems associated with an autonomous vehicle. For instance, MEMS microphone array apparatus 306 and/or MEMS microphone array apparatus 308 can include one or more MEMS microphones corresponding to sensor systems 404-408.

FIG. 4 illustrates an example of an AV management system 400. One of ordinary skill in the art will understand that, for the AV management system 400 and any system discussed in the present disclosure, there can be additional or fewer components in similar or alternative configurations. The illustrations and examples provided in the present disclosure are for conciseness and clarity. Other examples may include different numbers and/or types of elements, but one of ordinary skill the art will appreciate that such variations do not depart from the scope of the present disclosure.

In this example, the AV management system 400 includes an AV 402, a data center 450, and a client computing device 470. The AV 402, the data center 450, and the client computing device 470 can communicate with one another over one or more networks (not shown), such as a public network (e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

The AV 402 can navigate roadways without a human driver based on sensor signals generated by multiple sensor systems 404, 406, and 408. The sensor systems 404-408 can include different types of sensors and can be arranged about the AV 402. For instance, the sensor systems 404-408 can comprise Inertial Measurement Units (IMUs), cameras (e.g., still image cameras, video cameras, etc.), light sensors (e.g., LIDAR systems, ambient light sensors, infrared sensors, etc.), RADAR systems, GPS receivers, audio sensors (e.g., microphones, micro-electromechanical systems (MEMS) microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 404 can be a camera system, the sensor system 406 can be a LIDAR system, and the sensor system 408 can be a RADAR system. Other examples may include any other number and type of sensors.

The AV 402 can also include several mechanical systems that can be used to maneuver or operate the AV 402. For instance, the mechanical systems can include a vehicle propulsion system 430, a braking system 432, a steering system 434, a safety system 436, and a cabin system 438, among other systems. The vehicle propulsion system 430 can include an electric motor, an internal combustion engine, or both. The braking system 432 can include an engine brake, brake pads, actuators, and/or any other suitable componentry configured to assist in decelerating the AV 402. The steering system 434 can include suitable componentry configured to control the direction of movement of the AV 402 during navigation. The safety system 436 can include lights and signal indicators, a parking brake, airbags, and so forth. The cabin system 438 can include cabin temperature control systems, in-cabin entertainment systems, and so forth. In some aspects, the AV 402 might not include human driver actuators (e.g., steering wheel, handbrake, foot brake pedal, foot accelerator pedal, turn signal lever, window wipers, etc.) for controlling the AV 402. Instead, the cabin system 438 can include one or more client interfaces (e.g., Graphical User Interfaces (GUIs), Voice User Interfaces (VUIs), etc.) for controlling certain aspects of the mechanical systems 430-438.

The AV 402 can additionally include a local computing device 410 that is in communication with the sensor systems 404-408, the mechanical systems 430-438, the data center 450, and the client computing device 470, among other systems. The local computing device 410 can include one or more processors and memory, including instructions that can be executed by the one or more processors. The instructions can make up one or more software stacks or components responsible for controlling the AV 402; communicating with the data center 450, the client computing device 470, and other systems; receiving inputs from riders, passengers, and other entities within the AV's environment; logging metrics collected by the sensor systems 404-408; and so forth. In this example, the local computing device 410 includes a perception stack 412, a mapping and localization stack 414, a prediction stack 416, a planning stack 418, a communications stack 420, a control stack 422, an AV operational database 424, and an HD geospatial database 426, among other stacks and systems.

The perception stack 412 can enable the AV 402 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 404-408, the mapping and localization stack 414, the HD geospatial database 426, other components of the AV, and other data sources (e.g., the data center 450, the client computing device 470, third party data sources, etc.). The perception stack 412 can detect and classify objects and determine their current locations, speeds, directions, and the like. In addition, the perception stack 412 can determine the free space around the AV 402 (e.g., to maintain a safe distance from other objects, change lanes, park the AV, etc.). The perception stack 412 can also identify environmental uncertainties, such as where to look for moving objects, flag areas that may be obscured or blocked from view, and so forth. In some examples, an output of the prediction stack can be a bounding area around a perceived object that can be associated with a semantic label that identifies the type of object that is within the bounding area, the kinematic of the object (information about its movement), a tracked path of the object, and a description of the pose of the object (its orientation or heading, etc.).

The mapping and localization stack 414 can determine the AV's position and orientation (pose) using different methods from multiple systems (e.g., GPS, IMUS, cameras, LIDAR, RADAR, ultrasonic sensors, the HD geospatial database 426, etc.). For example, in some cases, the AV 402 can compare sensor data captured in real-time by the sensor systems 404-408 to data in the HD geospatial database 426 to determine its precise (e.g., accurate to the order of a few centimeters or less) position and orientation. The AV 402 can focus its search based on sensor data from one or more first sensor systems (e.g., GPS) by matching sensor data from one or more second sensor systems (e.g., LIDAR). If the mapping and localization information from one system is unavailable, the AV 402 can use mapping and localization information from a redundant system and/or from remote data sources.

The prediction stack 416 can receive information from the localization stack 414 and objects identified by the perception stack 412 and predict a future path for the objects. In some instances, the prediction stack 416 can output several likely paths that an object is predicted to take along with a probability associated with each path. For each predicted path, the prediction stack 416 can also output a range of points along the path corresponding to a predicted location of the object along the path at future time intervals along with an expected error value for each of the points that indicates a probabilistic deviation from that point.

The planning stack 418 can determine how to maneuver or operate the AV 402 safely and efficiently in its environment. For example, the planning stack 418 can receive the location, speed, and direction of the AV 402, geospatial data, data regarding objects sharing the road with the AV 402 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 402 from one point to another and outputs from the perception stack 412, localization stack 414, and prediction stack 416. The planning stack 418 can determine multiple sets of one or more mechanical operations that the AV 402 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 418 can select from multiple backup plans to carry out. For example, while preparing to change lanes to turn right at an intersection, another vehicle may aggressively cut into the destination lane, making the lane change unsafe. The planning stack 418 could have already determined an alternative plan for such an event. Upon its occurrence, it could help direct the AV 402 to go around the block instead of blocking a current lane while waiting for an opening to change lanes.

The control stack 422 can manage the operation of the vehicle propulsion system 430, the braking system 432, the steering system 434, the safety system 436, and the cabin system 438. The control stack 422 can receive sensor signals from the sensor systems 404-408 as well as communicate with other stacks or components of the local computing device 410 or a remote system (e.g., the data center 450) to effectuate operation of the AV 402. For example, the control stack 422 can implement the final path or actions from the multiple paths or actions provided by the planning stack 418. This can involve turning the routes and decisions from the planning stack 418 into commands for the actuators that control the AV's steering, throttle, brake, and drive unit.

The communications stack 420 can transmit and receive signals between the various stacks and other components of the AV 402 and between the AV 402, the data center 450, the client computing device 470, and other remote systems. The communications stack 420 can enable the local computing device 410 to exchange information remotely over a network, such as through an antenna array or interface that can provide a metropolitan WIFI network connection, a mobile or cellular network connection (e.g., Third Generation (3G), Fourth Generation (4G), Long-Term Evolution (LTE), 5^{th} Generation (5G), etc.), and/or other wireless network connection (e.g., License Assisted Access (LAA), Citizens Broadband Radio Service (CBRS), MULTEFIRE, etc.). The communications stack 420 can also facilitate the local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 426 can store HD maps and related data of the streets upon which the AV 402 travels. In some examples, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include 3D attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal u-turn lanes; permissive or protected only right turn lanes; etc.). The traffic controls lane can include geospatial information of traffic signal lights, traffic signs, and other road objects and related attributes.

The AV operational database 424 can store raw AV data generated by the sensor systems 404-408, stacks 412-422, and other components of the AV 402 and/or data received by the AV 402 from remote systems (e.g., the data center 450, the client computing device 470, etc.). In some cases, the raw AV data can include HD LIDAR point cloud data, image data, RADAR data, GPS data, and other sensor data that the data center 450 can use for creating or updating AV geospatial data or for creating simulations of situations encountered by AV 402 for future testing or training of various machine learning algorithms that are incorporated in the local computing device 410.

The data center 450 can be a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and so forth. The data center 450 can include one or more computing devices remote to the local computing device 410 for managing a fleet of Avs and AV-related services. For example, in addition to managing the AV 402, the data center 450 may also support a ridesharing service, a delivery service, a remote/roadside assistance service, street services (e.g., street mapping, street patrol, street cleaning, street metering, parking reservation, etc.), and the like.

The data center 450 can send and receive various signals to and from the AV 402 and the client computing device 470. These signals can include sensor data captured by the sensor systems 404-408, roadside assistance requests, software updates, ridesharing pick-up and drop-off instructions, and so forth. In this example, the data center 450 includes a data management platform 452, an Artificial Intelligence/Machine Learning (AI/ML) platform 454, a simulation platform 456, a remote assistance platform 458, and a ridesharing platform 460, and a map management platform 462, among other systems.

The data management platform 452 can be a “big data” system capable of receiving and transmitting data at high velocities (e.g., near real-time or real-time), processing a large variety of data and storing large volumes of data (e.g., terabytes, petabytes, or more of data). The varieties of data can include data having different structured (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., Avs, enterprise systems, social networks, etc.), data having different rates of change (e.g., batch, streaming, etc.), or data having other heterogeneous characteristics. The various platforms and systems of the data center 450 can access data stored by the data management platform 452 to provide their respective services.

The AI/ML platform 454 can provide the infrastructure for training and evaluating machine learning algorithms for operating the AV 402, the simulation platform 456, the remote assistance platform 458, the ridesharing platform 460, the map management platform 462, and other platforms and systems. Using the AI/ML platform 454, data scientists can prepare data sets from the data management platform 452; select, design, and train machine learning models; evaluate, refine, and deploy the models; maintain, monitor, and retrain the models; and so on.

The simulation platform 456 can enable testing and validation of the algorithms, machine learning models, neural networks, and other development efforts for the AV 402, the remote assistance platform 458, the ridesharing platform 460, the map management platform 462, and other platforms and systems. The simulation platform 456 can replicate a variety of driving environments and/or reproduce real-world scenarios from data captured by the AV 402, including rendering geospatial information and road infrastructure (e.g., streets, lanes, crosswalks, traffic lights, stop signs, etc.) obtained from a cartography platform (e.g., map management platform 462); modeling the behavior of other vehicles, bicycles, pedestrians, and other dynamic elements; simulating inclement weather conditions, different traffic scenarios; and so on.

The remote assistance platform 458 can generate and transmit instructions regarding the operation of the AV 402. For example, in response to an output of the AI/ML platform 454 or other system of the data center 450, the remote assistance platform 458 can prepare instructions for one or more stacks or other components of the AV 402.

The ridesharing platform 460 can interact with a customer of a ridesharing service via a ridesharing application 472 executing on the client computing device 470. The client computing device 470 can be any type of computing system, including a server, desktop computer, laptop, tablet, smartphone, smart wearable device (e.g., smartwatch, smart eyeglasses or other Head-Mounted Display (HMD), smart ear pods, or other smart in-ear, on-ear, or over-ear device, etc.), gaming system, or other general purpose computing device for accessing the ridesharing application 472. The client computing device 470 can be a customer's mobile computing device or a computing device integrated with the AV 402 (e.g., the local computing device 410). The ridesharing platform 460 can receive requests to pick up or drop off from the ridesharing application 472 and dispatch the AV 402 for the trip.

Map management platform 462 can provide a set of tools for the manipulation and management of geographic and spatial (geospatial) and related attribute data. The data management platform 452 can receive LIDAR point cloud data, image data (e.g., still image, video, etc.), RADAR data, GPS data, and other sensor data (e.g., raw data) from one or more Avs 402, Unmanned Aerial Vehicles (UAVs), satellites, third-party mapping services, and other sources of geospatially referenced data. The raw data can be processed, and map management platform 462 can render base representations (e.g., tiles (2D), bounding volumes (3D), etc.) of the AV geospatial data to enable users to view, query, label, edit, and otherwise interact with the data. Map management platform 462 can manage workflows and tasks for operating on the AV geospatial data. Map management platform 462 can control access to the AV geospatial data, including granting or limiting access to the AV geospatial data based on user-based, role-based, group-based, task-based, and other attribute-based access control mechanisms. Map management platform 462 can provide version control for the AV geospatial data, such as to track specific changes that (human or machine) map editors have made to the data and to revert changes when necessary. Map management platform 462 can administer release management of the AV geospatial data, including distributing suitable iterations of the data to different users, computing devices, Avs, and other consumers of HD maps. Map management platform 462 can provide analytics regarding the AV geospatial data and related data, such as to generate insights relating to the throughput and quality of mapping tasks.

In some aspects, the map viewing services of map management platform 462 can be modularized and deployed as part of one or more of the platforms and systems of the data center 450. For example, the AI/ML platform 454 may incorporate the map viewing services for visualizing the effectiveness of various object detection or object classification models, the simulation platform 456 may incorporate the map viewing services for recreating and visualizing certain driving scenarios, the remote assistance platform 458 may incorporate the map viewing services for replaying traffic incidents to facilitate and coordinate aid, the ridesharing platform 460 may incorporate the map viewing services into the client application 472 to enable passengers to view the AV 402 in transit en route to a pick-up or drop-off location, and so on.

The terminology used herein is for the purpose of describing particular examples only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The various examples described above are provided by way of illustration only and should not be construed to limit the scope of the disclosure. For example, the principles herein apply equally to optimization as well as general improvements. Various modifications and changes may be made to the principles described herein without following the example aspects and applications illustrated and described herein, and without departing from the scope of the disclosure.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

What is claimed is:

1. A micro-electromechanical system (MEMS) microphone apparatus comprising:
a monolithic housing having a non-uniform thickness, wherein the monolithic housing includes at least one portion having a thinner thickness than a remaining portion of the monolithic housing;
at least one acoustic port located proximate to an interior surface of the at least one portion of the monolithic housing; and
at least one micro-electromechanical system microphone sensor coupled to the at least one acoustic port.

2. The MEMS microphone apparatus of claim 1, wherein the at least one acoustic port comprises an annular opening between the at least one portion having a thinner thickness than a remaining portion of the monolithic housing and the at least one micro-electromechanical system microphone sensor.

3. The MEMS microphone apparatus of claim 2, wherein the annular opening is dimensioned to converge from the at least one portion of the monolithic housing to the at least one micro-electromechanical system microphone sensor.

4. The MEMS microphone apparatus of claim 2, wherein the annular opening is dimensioned to diverge from the at least one portion of the monolithic housing to the at least one micro-electromechanical system microphone sensor.

5. The MEMS microphone apparatus of claim 1, wherein the at least one portion of the monolithic housing is flush with an exterior surface of the monolithic housing.

6. The MEMS microphone apparatus of claim 1, wherein the at least one portion of the monolithic housing is positioned within the at least one acoustic port.

7. The MEMS microphone apparatus of claim 1, wherein the thinner thickness of the at least one portion of the monolithic housing is less than or equal to 0.15 millimeters.

8. The MEMS microphone apparatus of claim 1, wherein the monolithic housing is configured to form a watertight seal over the at least one acoustic port.

9. A micro-electromechanical system (MEMS) microphone apparatus comprising:
a housing;
at least one acoustic port extending through the housing; and
at least one membrane positioned within the at least one acoustic port, wherein the at least one membrane is configured to seal the at least one acoustic port.

10. The MEMS microphone apparatus of claim 9, wherein the at least one membrane is positioned concentrically at an exterior edge of the at least one acoustic port.

11. The MEMS microphone apparatus of claim 9, wherein the at least one membrane is flushed with an exterior surface of the housing.

12. The MEMS microphone apparatus of claim 9, further comprising:
a micro-electromechanical system microphone sensor receptor positioned proximate to the at least one acoustic port.

13. The MEMS microphone apparatus of claim 9, wherein the at least one acoustic port is configured to couple to a micro-electromechanical system microphone sensor.

14. The MEMS microphone apparatus of claim 9, wherein the at least one acoustic port comprises an annular opening.

15. The MEMS microphone apparatus of claim 14, wherein the annular opening is dimensioned to converge from an interior edge of the at least one acoustic port to an exterior edge of the at least one acoustic port.

16. The MEMS microphone apparatus of claim 14, wherein the annular opening is dimensioned to diverge from an interior edge of the at least one acoustic port to an exterior edge of the at least one acoustic port.

17. The MEMS microphone apparatus of claim 14, wherein the at least one membrane is positioned within the annular opening of the at least one acoustic port.

18. The MEMS microphone apparatus of claim 9, wherein a thickness of the at least one membrane is less than or equal to 0.15 millimeters.

19. An autonomous vehicle comprising:
one or more audio sensors positioned on an exterior portion of the autonomous vehicle;
one or more acoustic ports coupled to the one or more audio sensors; and
an audio sensor housing having one or more membranes configured to cover the one or more acoustic ports.

20. The autonomous vehicle of claim 19, wherein the audio sensor housing comprises:
a monolithic housing having a non-uniform thickness, wherein the monolithic housing includes the one or more membranes, wherein the one or more membranes have a thinner thickness than a remaining portion of the monolithic housing;
at least one acoustic port located proximate to an interior surface of the one or more membranes; and
at least one micro-electromechanical system microphone sensor coupled to the at least one acoustic port.
